(19) United States
(12) Patent Application Publication
(10) Pub. No.: US 2009/0325391 A1
(43) Pub. Date: Dec. 31, 2009

(54) OZONE AND TEOS PROCESS FOR SILICON OXIDE DEPOSITION

(75) Inventors: Stijn DE VUSSER, Heverlee (BE); Pamela R. Fischer, Leuven (BE); Lieve Vandezande, Tielt-Winge (BE)

Correspondence Address: KNOBBE MARTENS OLSON & BEAR LLP, 2040 MAIN STREET, FOURTEENTH FLOOR, IRVINE, CA, 92614, US

(73) Assignee: ASM INTERNATIONAL NV, Bilthoven (NL)

(21) Appl. No.: 12/165,497

(22) Filed: Jun. 30, 2008

(51) Int. Cl. H01L 21/31

(52) U.S. Cl. 438/787; 257/E21.24

(57) ABSTRACT

Methods for depositing silicon oxide in a batch reactor are provided. In some embodiments, a plurality of vertically separated substrates is provided in a reaction chamber. Tetraethyl orthosilicate (TEOS) is pulsed into the reaction chamber by direct liquid injection. Ozone is flowed into the reaction chamber simultaneously or alternately with the TEOS. The deposition is performed at about 10 Torr or less to extend the mean free path length of the ozone molecules. According to some embodiments, the deposition allows openings in the substrates to be filled while the occurrence of voids is maintained at a low level.

### BACKGROUND OF THE INVENTION

1. Field of the Invention

This invention relates generally to integrated circuit fabrication and, more particularly, the formation of silicon oxide layers.

2. Description of the Related Art

As the dimensions of microelectronic devices becomes smaller in order to increase device density and facilitate the miniaturization of integrated circuits, the limitations in fabrication processes become more noticeable. For example, as the sizes of devices decrease, the widths of some integrated circuit features, such as openings, also decrease. However, there is typically not a similar decrease in the depths of these openings, thereby causing an increase in the aspect ratios of the features.

In some integrated circuit fabrication processes, material is deposited into openings in substrates to form various parts of the integrated circuit. For example, dielectric materials, such as silicon oxide, can be deposited into openings to form, e.g., shallow trench isolation structures. However, depositing material into such openings, including trenches, can create voids in the openings, as the deposited material can preferentially deposit at the mouth of the openings. In some cases, the material forms bridges at the mouth, which pinches off deposition into the opening and causes the formation of large voids in the openings. As the widths of openings decrease, the likelihood of this pinching and void formation increases. These voids can reduce the performance of the integrated circuits and also can reduce manufacturing throughput when the resulting integrated circuits do not meet performance specifications.

Accordingly, as the dimensions of integrated circuit features continue to decrease, there is a continuing need for methods for depositing materials as deposition requirements become more stringent.

### SUMMARY

In some embodiments, a method for depositing silicon oxide is provided. The method comprises providing a batch reactor and a plurality of vertically separated substrates in a reaction chamber of the batch reactor and chemical vapor depositing silicon oxide on the substrates. Chemical vapor depositing comprises pulsing tetraethyl orthosilicate (TEOS) into the reaction chamber and flowing ozone into the reaction chamber while maintaining a pressure inside the reaction chamber at about 10 Torr or less.

In some other embodiments, a method for depositing silicon oxide on a substrate is provided. The method comprises providing the substrate in a reaction chamber, pulsing TEOS into the reaction chamber, and flowing ozone into the reaction chamber while maintaining a pressure inside the reaction chamber at about 10 Torr or less. The amount of TEOS flowed into the reaction chamber per pulse varies among the series of TEOS pulses.

In still other embodiments, a method for depositing silicon oxide is provided. The method comprises providing a substrate in a reaction chamber, the substrate having a trench, and filling the trench with silicon oxide. Filling the trench comprises pulsing TEOS into the reaction chamber, flowing ozone into the reaction chamber, and maintaining a pressure inside the reaction chamber at about 10 Torr or less.

### BRIEF DESCRIPTION OF THE DRAWINGS

The invention will be better understood from the detailed description of the preferred embodiments and from the appended drawings, which are meant to illustrate and not to limit the invention and wherein like numerals refer to like parts throughout.

FIG. 1 is a schematic cross-sectional side view of an elongated batch reactor with a gas injector, in accordance with some embodiments of the invention.

FIG. 2 is a front view of a gas injector for use with the batch reactor of FIG. 1, in accordance with some embodiments of the invention.

FIG. 3 is a gas flow schematic showing reactant sources in connection with the reactor of FIG. 1, in accordance with some embodiments of the invention.

FIG. 4 is a schematic diagram showing a deposition process where the deposition pressure and temperature vary as a function of time, in accordance with some embodiments of the invention.

FIG. 5 is a schematic diagram showing a deposition process in which a series of TEOS pulses is introduced into a reaction chamber while ozone is flowed continuously, in accordance with some embodiments of the invention.

FIG. 6 is a schematic diagram showing a deposition process in which a series of TEOS pulses is introduced into a reaction chamber, the amount of TEOS delivered per pulse varying as a function of time, while the amount of ozone delivered into the chamber is also varied over time, in accordance with some embodiments of the invention.

FIG. 7 is a schematic diagram showing a deposition process in which a series of TEOS pulses and a series of ozone pulses are alternatively introduced into a reaction chamber, in accordance with some embodiments of the invention.

FIG. 8 is a schematic diagram showing a deposition process in which a series of TEOS pulses and a series of ozone pulses are alternatively introduced into a reaction chamber, with the amount of TEOS and ozone delivered per pulse varying as a function of time, in accordance with some embodiments of the invention.

FIG. 9 is a graphical representation comparing the deposition rate of a deposition process involving the reactants TEOS and O₂ with deposition process involving the reactants TEOS and O₃, in accordance with some embodiments of the invention.

FIG. 10 is a scanning electron micrograph (SEM) showing trenches formed by a deposition process using the reactants TEOS and O₂.

FIG. 11 is a SEM showing trenches formed by a deposition process using the reactants TEOS and O₃ introduced into the reaction chamber at a constant flow rate.

FIG. 12 is a SEM showing trenches formed by a deposition process using the reactants TEOS and O₃ introduced into the reaction chamber in pulses, in accordance with some embodiments of the invention.

### DETAILED DESCRIPTION

Batch reactors were once the dominant reactors for depositing films on substrates. These reactors accommodate and can deposit films on a plurality of substrates. However, due to various factors, such as difficulties uniformly controlling the deposition environment immediately adjacent each substrate, achieving consistently high quality deposition results can be difficult.

As deposition requirements have become more stringent, single substrate reactors have become more dominant for some demanding depositions, such as depositing highly conformal films or filling openings having high aspect ratios. For example, it can be difficult to fill trenches with aspect ratios of about 4 or more, or about 5 or more, with silicon oxide. Single substrate reactors accommodate a single substrate and the small volumes of these reactors allow a high degree of optimization, thereby facilitating high quality deposition results on that substrate. For example, sub-atmospheric chemical vapor deposition (CVD) processes in single substrate reactors, with deposition pressures of several hundred Torr, have been used to deposit highly conformal silicon oxide films on substrates.

It will be appreciated that silicon oxide films can be deposited using tetraethyl orthosilicate (TEOS) and an oxygen precursor, such as ozone (O₃). O₃ is prone to decomposition, which adversely affects the deposition. However, this concern is small for the small volume of typical single substrate reactors, since the O₃ only traverses a relatively small distance in a reaction chamber, before contacting the substrate. The concern is more serious for batch reactors, which have large volumes that require the O₃ to traverse relatively large distances before contacting and depositing on a substrate. In addition, O₃ molecules can interact with a large number of other surfaces before contacting a substrate. For example, the O₃ can react with reaction chamber walls, the undersides of substrate supports, and other wafer boats surfaces.

Advantageously, in spite of these concerns, the inventors have developed a process that allows for high quality silicon oxide deposition results in a batch reactor. To reduce the occurrence of the decomposition of O₃, the mean free path length of O₃ molecules traveling through the reaction chamber is increased. In some embodiments, the mean free path length is increased by about 400 times, relative to the mean free path length of O₃ molecules in a deposition process at 600 Torr. Advantageously, it has been found that the mean free path length can be increased by conducting the deposition under low pressure, e.g., at about 10 Torr or less, about 5 Torr or less, or about 1.5 Torr or less.

In addition, in some embodiments, the deposition is performed in a hot wall batch reactor. Advantageously, the hot walls of the reaction chamber of the reactor minimize the deposition of reactants, such as O₃ on those walls. As a result, the number of molecules of the reactants available to react with the substrates is increased, and the particle generation caused by flaking of deposited material off the walls is decreased, relative to depositions in which reactants deposit on the reaction chamber walls.

Also, in some embodiments, direct liquid injection (DLI) is used to deliver TEOS to the reaction chamber. For the DLI system, an evaporator is used to vaporize liquid TEOS. The evaporator allows the TEOS flow to be metered and controlled in the liquid phase, which allows more precise control of the amount of TEOS provided into a reaction chamber, relative to vaporizing the TEOS using a conventional bubbler. A carrier gas for the TEOS can be omitted, such that substantially pure TEOS vapor can be delivered to the reaction chamber. As a result of the highly precise control of TEOS into the chamber, excellent control of film properties can be achieved.

Advantageously, depositions according to preferred embodiments of the invention allow for the filling of openings, or trenches, in a batch reactor with an exceptionally low occurrence, or preferably an omission, of voids. Openings having aspect ratios of about 4 or more, or about 5 or more, can be filled with a low occurrence of voids. In addition, preferred embodiments of the invention deposit films having low levels of stress, which can have benefits for increasing the reliability of devices incorporating the films.

In some embodiments, silicon oxide is deposited on substrates in a batch reaction chamber. To deposit the silicon oxide, a silicon precursor is flowed into the batch reaction chamber. The amount of the silicon precursor flowed into the batch reaction chamber varies as a function of time. For example, the silicon precursor can be pulsed into the reaction chamber. Between the pulses, the silicon precursor can be removed from the chamber, e.g., by evacuation or by purging with purge gas, such as an inert gas. An oxygen precursor is also flowed into the chamber to react with silicon species, thereby forming a silicon oxide layer. The flow of the oxygen precursor can overlap the flow of the silicon precursor into the reaction chamber, or can alternate with pulses of the silicon precursor. In some embodiments, the oxygen precursor is flowed continuously into the reaction chamber at a constant rate and in some other embodiments, the flow rate of the oxygen precursor is varied over time. The deposition is continued as desired to fill openings on the surface of the substrate, such as trenches, and to form silicon oxide layers having a desired thickness on the substrate surface. In preferred embodiments, the silicon source precursor is tetraethyl orthosilicate (TEOS) and the oxygen source precursor is ozone.

Reference will now be made to the Figures, wherein like numerals refer to like parts throughout.

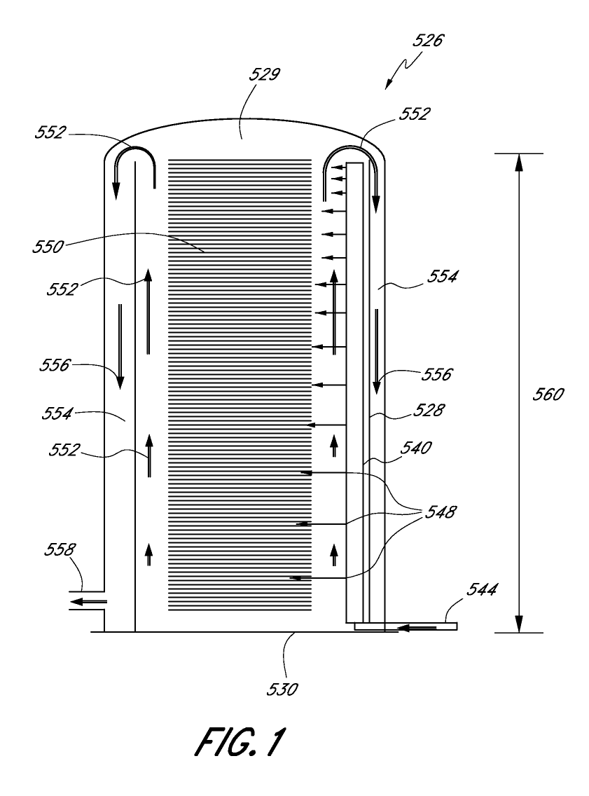

FIG. 1 illustrates an example of a batch reactor, shown in a schematic cross-sectional side-view. The illustrated reactor is commercially available under the trade name Advance 412™ or A412™ from ASM International N.V. of Bilthoven, The Netherlands. The illustrated reactor is a vertical furnace type of reactor, which has benefits for efficient heating and loading sequences, but the skilled artisan will appreciate that the principles and advantages disclosed herein will have application to other types of reactors.

With continued reference to FIG. 1, a reactor 526 has a reaction chamber 529 which is preferably surrounded by a heating element (not shown). A liner 528, delimiting the outer perimeter of the reaction chamber 529, is preferably provided inside the reactor 526. Preferably, at the bottom of the reactor 526, a substrate load 550 may enter and exit the reactor 526 by a door 530. In some embodiments, the substrate load 550 can include 25 or more, or 50 or more, or 75 or more substrates. Precursor source gas is injected through a gas injector 540, preferably via a gas feed conduit 544. The gas injector 540 is provided with a pattern of holes 548, preferably extending substantially over the height of the substrate load 550. Note that, because gases are first introduced into the reaction chamber 529 from the holes 548 of the gas injector 540, the interior of gas delivery devices, such as the gas injector 540, through which gases travel is not part of the reaction chamber 529 and is, in a sense, outside of the reaction chamber 529. Consequently, the reaction chamber 529 comprises the interior volume of the reactor 526, excluding the volume occupied by gas delivery devices such as the gas injector 540.

Substrates are held in a load 550 mounted on a sleeveless pedestal (not shown). The substrate load 550 may be made from quartz or other suitable materials and may be configured to contain between about 25 and about 150 slots. The sleeveless pedestal reduces heat loss at the bottom of the batch reactor 526 and acts as a shield for the door plate and the flange (not shown). In some embodiments, the substrate load 550 and sleeveless pedestal are turned inside the reactor 526 due to a rotating door plate (not shown).

In some embodiments, inside the process chamber 526, gas is flowed in a generally upward direction 552 and then removed from the reaction chamber 529 via an exhaust space 554 at the periphery of the chamber 529. Gas flows through the exhaust space 554 in a downward direction 556 to the exhaust 558, which is connected to a pump (not shown). The gas injector 540 preferably distributes process gases inside the reactor 526 over the entire height of the reaction chamber 529. The gas injector 540 itself acts as a restriction on the flow of gas, such that the holes 548 that are closer to the conduit 544 tend to inject more gas into the reaction space than those holes 548 that are farther from the conduit 544. Preferably, this tendency for differences in gas flows through the holes 548 can be compensated to an extent by reducing the distance between the holes 548 (i.e., increasing the density of the holes 548) as they are located farther away from the conduit 544. In other embodiments, the sizes of individual holes making up the holes 548 can increase with increasing distance from the conduit 544, or both the size of the holes 548 can increase and also the distance between the holes 48 can decrease with increasing distance from the conduit 544.

The injector 540 is advantageously designed to reduce the pressure inside the gas injector, resulting in a reduction of the gas phase reactions within the injector, since reaction rates typically increase with increasing pressure. While such reduced pressure can also lead to a poor distribution of gas over the height of the gas injector 540, the distribution of holes 548 across the height of the injector 540 is selected to improve uniformity of gas distribution.

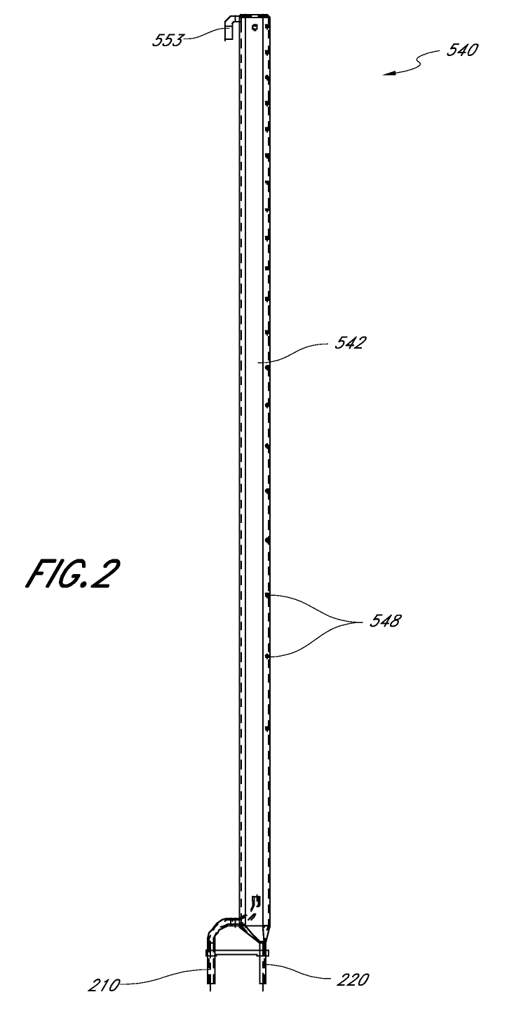

The gas injector 540 in accordance with some embodiments of the invention is shown in greater detail in FIG. 2. The gas injector 540 includes a gas injector tube 542, preferably provided with two separate gas feed conduit connections 210 and 220, respectively. The gas injector tube 542 injects gas into the reaction chamber 529 (FIG. 1) out of holes 548. At its top end, the gas injector 540 can be provided with a hook 553, to secure the top end of the gas injector 540 to a hook support inside the reactor 526 (FIG. 1).

As seen in FIG. 2, in some embodiments, the gas injector 540 has two inlets 210, 220, corresponding to a first precursor and a second precursor. In some embodiments, the first precursor, for example a silicon precursor (e.g., TEOS), can be flowed into the reaction chamber 529 via the first inlet 210 and then removed from the chamber 529 via the exhaust space 554 and the exhaust 558. The second precursor, for example an oxygen precursor (e.g., ozone), can be introduced into the reaction chamber 529 via the second inlet 220. The oxygen precursor reacts with the silicon precursor to form a layer of silicon oxide on the substrates 550 (FIG. 1). The second precursor can also be removed from the chamber 529 via the exhaust space 554 and the exhaust 558. In some embodiments, the silicon precursor and the oxygen precursor are introduced in alternating pulses. Between the pulses, or each precursor, the flow of the precursor can be stopped and the precursor can be removed from the reaction chamber, e.g., by purging or evacuation. In some other embodiments, the silicon precursor and the oxygen precursor are introduced into the gas injector simultaneously via the first and second inlets 210, 220 and mixed in the gas injector 540 before being pumped into the batch reactor.

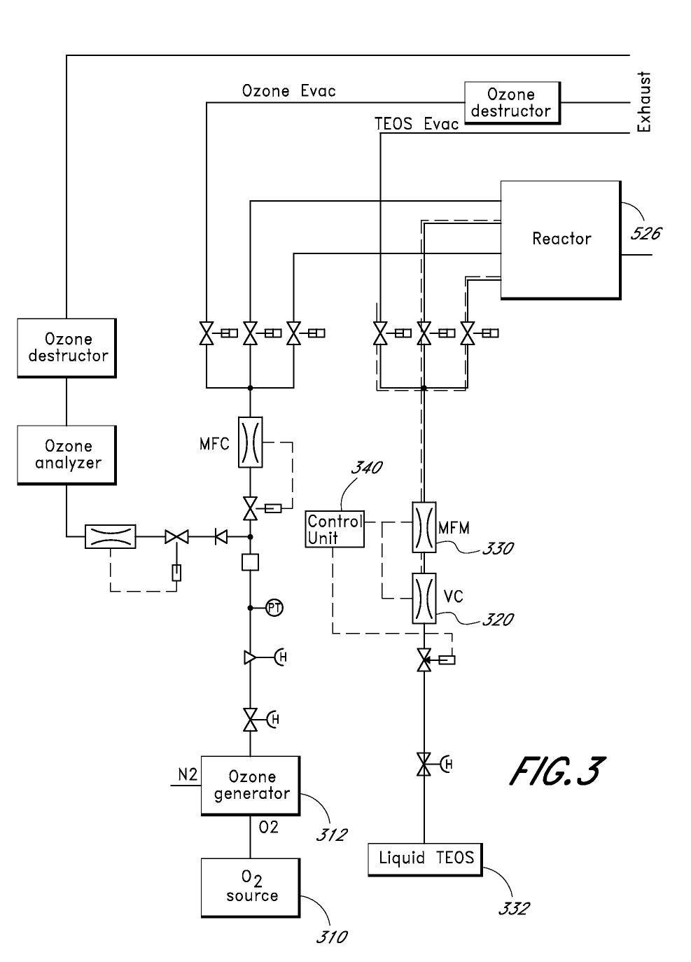

FIG. 3 is a gas flow schematic showing precursor sources in connection with the reactor 526. In some embodiments, ozone is generated from O₂. Oxygen is flowed from an oxygen source 310 into an ozone generator 312 to form ozone. As a result, the deposition inside the reaction chamber 526 (FIG. 1) is a non-plasma process. The output of the ozone generator comprises a fraction of ozone in O₂ but will be referred to herein as “ozone” or O₃.

It will be appreciated that liquid precursors, e.g., TEOS, can be delivered to the reactor by various methods, including using bubblers. In some preferred embodiments, as illustrated in FIG. 3, TEOS is delivered to the batch reactor 526 by direct liquid injection (DLI). DLI allows the flow of the TEOS to be controlled while the TEOS is in the liquid phase, thereby allowing more precise control of the TEOS flow than bubbler systems. In some embodiments, DLI comprises pushing the liquid precursor, which is stored in a containment unit 332, such as a metal canister, out of the containment unit 332 by pressurizing the canister with a gas, such as nitrogen. In some other embodiments, DLI comprises pumping the liquid precursor out of the containment unit 332. The liquid is flowed to and then vaporized in an evaporator unit 320. Evaporator unit 320 comprises a liquid flow controller to control the mass flow of the precursor in the liquid state and an evaporator. The precursor flow in the vaporized state can be measured by a mass flow meter 330.

The measurement signal of vaporized TEOS is routed via a control unit 340 in a feedback control loop to the liquid flow controller of the evaporator unit 320 to control the flow of liquid TEOS that is evaporated to form a TEOS gas. All gas lines downstream of the evaporator unit 320 can be heated, as shown by the dashed line, to prevent condensation along the flow path of the gas. In order to prevent condensation of the precursor gas, the evaporator unit 320, the mass flow meter 330, and TEOS carrying lines are heated, e.g., to between about 140° C. and about 150° C., by means of jackets (not shown) fixed along the process flow route. In some embodiments, DLI provides a TEOS gas flow of up to about 500 sccm.

Vaporized TEOS is then distributed in the reaction chamber 529 (see FIG. 1), by the injector 540. The configuration of holes along the injector 540 provides a uniform distribution of precursors along the plurality of substrates. The precursors contact the substrates and deposit material on them.

For each precursor, TEOS, as well as ozone, two gas feed lines are available for feeding the precursors into the reactor: one feed line connects to the injector for a distributed injection and an additional feed line connects to the flange in the bottom of the reactor. The additional feed line allows for tuning of the uniformity of deposited films in the down boat regions of the reactor.

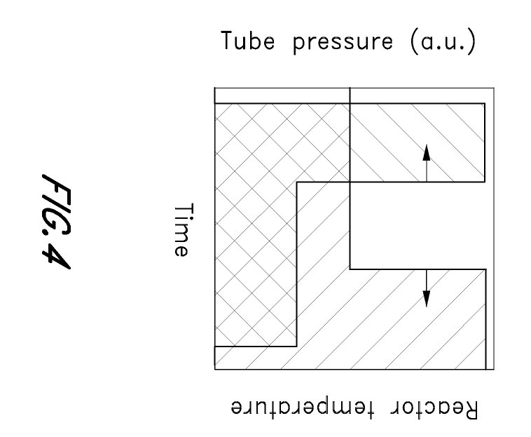

With reference to FIG. 4, some embodiments of the invention may include varying the temperature and pressure of the reaction chamber during a deposition. The variation in temperature and pressure can have advantages for increasing conformality and step coverage, controlling uniformity of deposition, and reducing formation of voids in the substrate features while increasing throughput.

As illustrated in FIG. 4, some embodiments include a temperature-pressure profile having multiple deposition regimes. In the illustrated embodiment, in the first deposition regime, the deposition temperature is at a first temperature set point and the pressure is at a first pressure set point. In the second deposition regime, the temperature remains the same, but the pressure is lowered to a second pressure set point. In the third deposition regime, the pressure remains substantially the same as in the second deposition regime, but the temperature increases to a second temperature set point. The increase in temperature increases the rate of silicon oxide formation. The temperature-pressure profile allows for conformal and high throughput depositions in a batch reactor by favoring uniformity and conformality early in the deposition process, and the temperature is then increased to speed up the formation of silicon oxide to favor high throughout processing. While the invention is not limited by theory, the low temperature regimes have a lower deposition rate and higher conformality, while the increase in temperature increases the deposition rate and the decrease in pressure is believed to further increase the mean free path of the silicon and oxygen source precursors, which allows the precursors to flow into openings, contact and react with the inner side walls of the openings to fill the features to still achieve low levels of void formation at the higher temperatures.

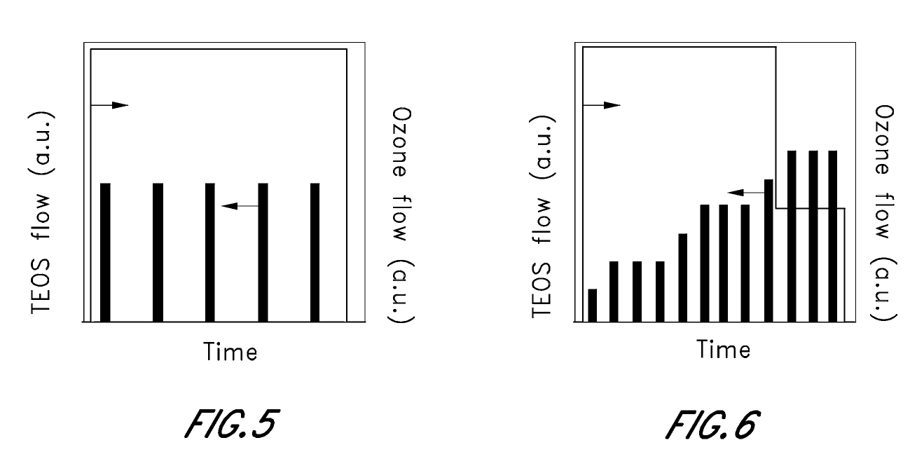

With reference to FIGS. 5-8, some embodiments of the invention include pulsing tetraethyl orthosilicate (TEOS) into a reaction chamber in fixed amounts or in varying amounts per pulse as a function of time and flowing ozone into the reaction chamber at one or more rates, including constantly flowing ozone, or pulsing the ozone into the reaction chamber in fixed amounts or in varying amounts per pulse as a function of time. In FIGS. 5-8, the shaded bars correspond to the TEOS flow. This is also indicated by the leftward pointing arrow from a shaded bar to the left axis labeled “TEOS flow.” The unshaded bars correspond to the ozone flow. This is also indicated by the rightward pointing arrow from an unshaded bar to the right axis labeled “Ozone flow.”

As seen in FIG. 5, TEOS is pulsed into the reaction chamber while ozone is simultaneously flowed into the reaction chamber. A constant amount of ozone is delivered to the chamber per unit time, e.g., the ozone flow rate is maintained at a constant level throughout the deposition and across the pulses of TEOS. In addition, the pulses of TEOS deliver a constant amount of TEOS to the chamber, per pulse. It will be appreciated that the amount of precursor delivered to the chamber can be controlled by selection of the pulse duration or the precursor flow rate. In some embodiments, the duration of each pulse and the flow rate for each pulse are constant. It will be appreciated that the durations and flow rates can be selected as desired, in view of desired film and deposition properties, such as conformality, step coverage, defect (or void) formation and deposition rate.

In some other embodiments of the invention, as illustrated in FIG. 6, TEOS is pulsed into the reaction chamber, with the amount of TEOS that is delivered per pulse varying with time. Ozone is continuously flowed into the chamber and the ozone flow overlaps with the TEOS flow. The ozone flow can deliver ozone to the chamber at a constant rate or, as illustrated, the rate can decrease over time.

With continued reference to FIG. 6, in the illustrated embodiment, the amount of TEOS delivered in each subsequent pulse is equal to or greater than the previous pulse. Concurrent with the introduction of TEOS pulses into the reaction chamber, ozone is flowed into the reaction chamber at a first flow rate and then the flow rate is changed to a second lower flow rate. A relatively low ratio of TEOS to ozone has been found to provide high conformality, at the expense of deposition rate, while a relatively high TEOS:ozone ratio increases the deposition rate, but with poorer conformality relative to the lower ratio. The lower initial TEOS flow rate pulses can aid in filling narrower, higher aspect ratio openings or trenches, and the subsequent increase in the amount of TEOS pulsed into the reaction chamber speeds up the rate of deposition in order to reach a desired thickness. As shown in FIG. 6, the ozone flow rate can be reduced, as the TEOS flow rate is increased, to increase the TEOS:ozone ratio. In some other embodiments, at a stage during a deposition process, decreases in the amount of TEOS delivered per pulse over time are also contemplated, e.g., to decrease the TEOS:ozone ratio

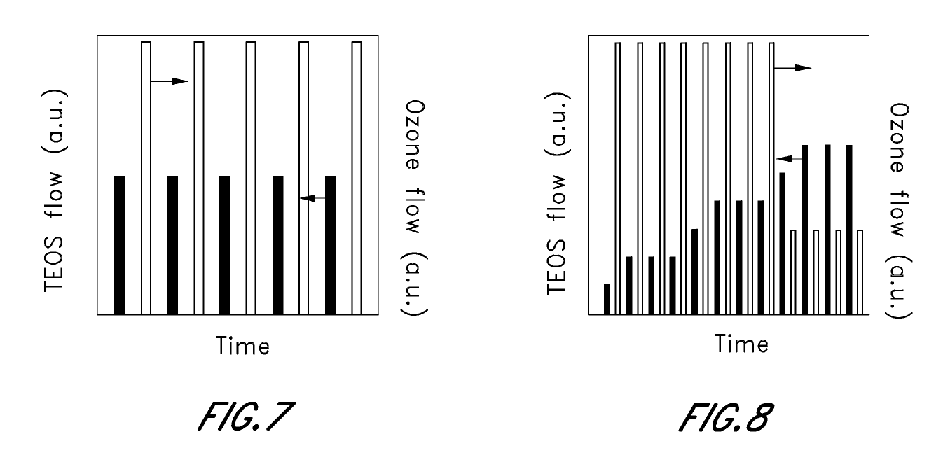

In some further embodiments of the invention, TEOS and ozone are separately pulsed into the reaction chamber. As illustrated in FIG. 7, in some embodiments, the amount of TEOS in each pulse and the amount of ozone in each pulse remain constant throughout the deposition process. Silicon is deposited on substrates by the TEOS pulses and the ozone from the ozone pulses reacts with the silicon to form silicon oxide. An excess of ozone is provided in the ozone pulses, relative to the TEOS provided in the TEOS pulses. As noted herein, a low TEOS:ozone ratio, e.g., less than 1:1, promotes high conformality

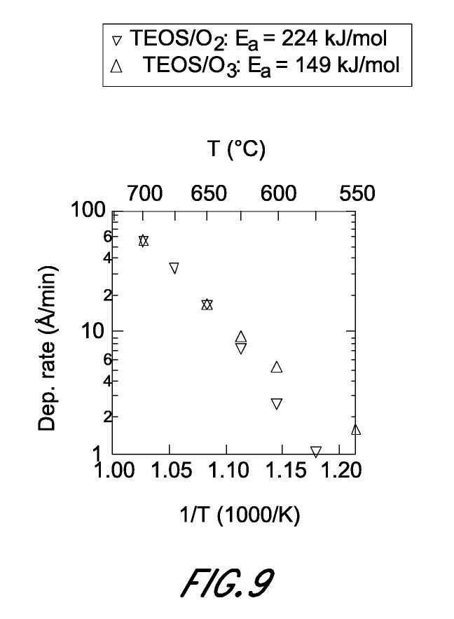

In some other embodiments of the invention, the amount of TEOS delivered per TEOS pulse and/or the amount of ozone delivered per ozone pulse is varied as a function of time. As illustrated in FIG. 8, in some embodiments, TEOS is introduced into the reaction chamber such that each subsequent pulse delivers an amount of TEOS that is equal to or greater than the previous TEOS pulse, although, as discussed herein, decreases over time in the amount of TEOS delivered per pulse is also contemplated. Ozone may be pulsed into the reaction chamber between the TEOS pulses, such that the TEOS and ozone pulses alternate. The ozone flow rate can be reduced, as the TEOS flow rate is increased, to increase the TEOS:ozone ratio, with the purpose of increasing the deposition rate towards the end of the deposition, e.g., after narrow, high aspect ratio trenches have been filled.

With reference to FIGS. 4-8, it be appreciated that deposition conditions can be selected to achieve desired film and deposition properties. In some embodiments, the deposition pressure is about 10,000 mTorr or less, or is in the range between about 100 mTorr and about 5000 mTorr, or between about 250 mTorr and about 2000 mTorr; and the deposition temperature is in the range between about 500° C. and about 700° C., or between about 550° C. and about 650° C.

In addition to deposition pressure and temperature, it will be appreciated that film and deposition properties can be tailored by controlling the ratio of TEOS to ozone. In some embodiments, the ratio of TEOS to ozone may be in the range from about 1:1000 to about 1:1. When the ratio of TEOS to ozone is low, the deposition rate is lower and the conformality of deposition is higher. As noted herein, in some embodiments, it may be advantageous to begin the deposition sequence with a relatively low TEOS:ozone flow rate until the narrowest trenches have been filled, and then increasing the TEOS flow in order to increase the deposition rate.

A relatively low TEOS:ozone ratio can also increase the density of deposited silicon oxide films. The resulting films have superior etch protection properties, e.g., for use as etch stops. It will be appreciated that deposited films can be annealed to increase density. Advantageously, forming highly dense films, as deposited, can remove the need for the densification anneal.

In some embodiments, e.g., in modifications of the illustrated embodiments of FIGS. 6 and 8, the silicon oxide deposition starts with a low first TEOS:ozone ratio which favors conformality (e.g., to fill relatively narrow, high aspect ratio openings), the ratio is subsequently increased to a second higher TEOS:ozone ratio to increase the deposition rate (e.g., after filling the high aspect ratio openings), and the ratio is then decreased to a third lower TEOS:ozone ratio to increase the density of the upper surface of the deposited film.

In some embodiments, with reference to FIGS. 5-8, each pulse of TEOS is in the range between about 10 seconds and about 3 minutes long, or about 60 seconds, about 30 seconds, or about 15 seconds long. In some embodiments, the interval between two pulses is between about 10 seconds to about 5 minutes, or about 1 minute, about 2 minutes, or about 3 minutes. The interval between alternating pulses may be evenly spaced or varied.

It will be appreciated that the pressure/temperature profile of FIG. 4 can be overlaid the various precursor flow profiles of FIGS. 5-8. As noted herein, a high pressure/low temperature initial deposition regime has advantages for high step coverage and conformality, e.g., for initially filling relatively narrow, high aspect ratio openings, while a lower pressure/higher temperature regime has advantages for increasing throughput.

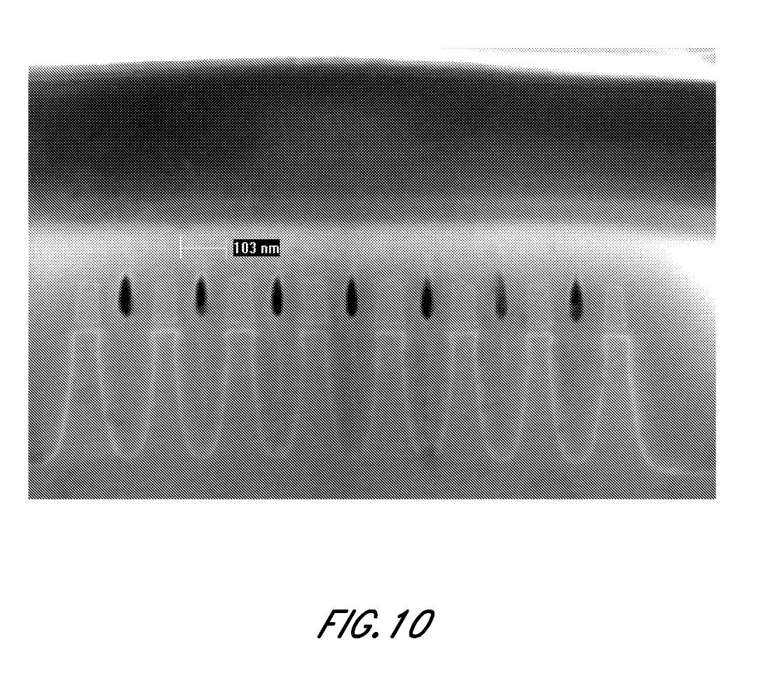

It will also be appreciated that deposition with ozone provides various advantages. FIG. 9 illustrates a comparison in the deposition rates between a TEOS/oxygen process and a TEOS/ozone process as a function of temperature and pressure. The deposition rate of both TEOS/oxygen and TEOS/ozone increases with increases in temperature and pressure. Advantageously, at lower temperatures and lower pressures, the rate of deposition of TEOS/ozone is higher than TEOS/oxygen.

### EXAMPLE 1

Using TEOS and O₂ as precursors, silicon oxide was formed on substrates containing trenches about 100 nm wide and having an aspect ratio of about 4. The deposition was performed in a A412™ batch reactor from ASM International N.V. of Bilthoven, The Netherlands. TEOS and oxygen were flowed into the reaction chamber of the reactor continuously and simultaneously, at a constant rate. TEOS was flowed at about 100 sccm and O₂ was flowed at about 13 sccm. The substrate temperature was about 675° C. The reaction chamber pressure was about 250 mTorr. A total thickness of about 650 nm of silicon oxide was deposited.

The substrates were then annealed in two stages in an ASM A412™ wet oxide vertical furnace from ASM International N.V. of Bilthoven, The Netherlands. First, the substrates are annealed at 750° C. for 30 minutes in a steam atmosphere. Second, the substrates are annealed at 1050° C. for 30 minutes in a nitrogen atmosphere.

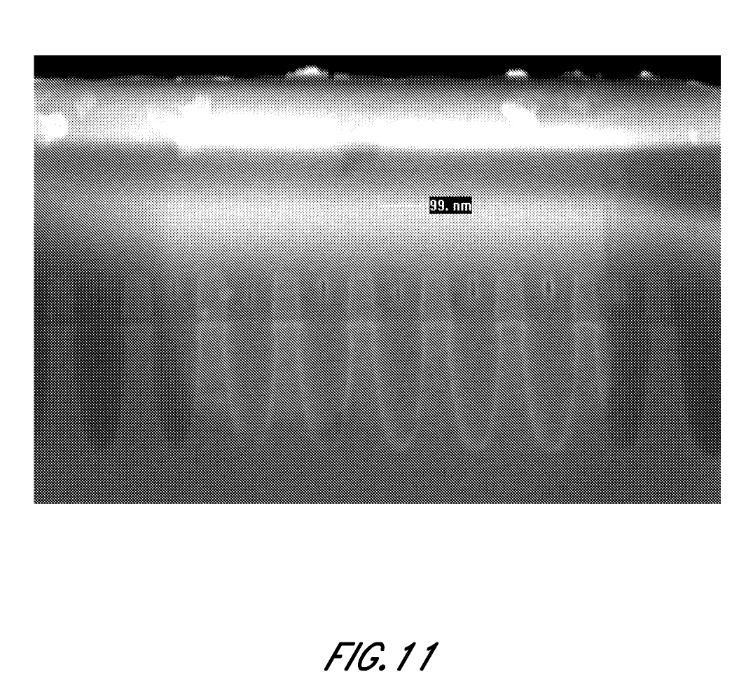

FIG. 10 illustrates the results of the deposition. Large voids were notably apparent in the silicon oxide deposited into the openings.

### EXAMPLE 2

Silicon oxide was deposited into trenches using TEOS and O₃ as precursors flowed continuously and simultaneously into a reaction chamber at a constant rate. The trenches were about 100 nm wide, with an aspect ratio of about 4. The deposition was performed in a A412™ batch reactor from ASM International N.V. of Bilthoven, The Netherlands. TEOS and ozone were flowed into the reaction chamber. TEOS was flowed at about 450 sccm and ozone was flowed at about 0.15 slm. The substrate temperature was about 600° C. and the reaction chamber pressure was about 1500 mTorr. A total thickness of about 650 nm of silicon oxide was deposited.

The substrates were then annealed in two stages in an ASM A412™ wet oxide vertical furnace from ASM International N.V. of Bilthoven, The Netherlands. First, the substrates are annealed at 750° C. for 30 minutes in a steam atmosphere. Second, the substrates are annealed at 1050° C. for 30 minutes in a nitrogen atmosphere.

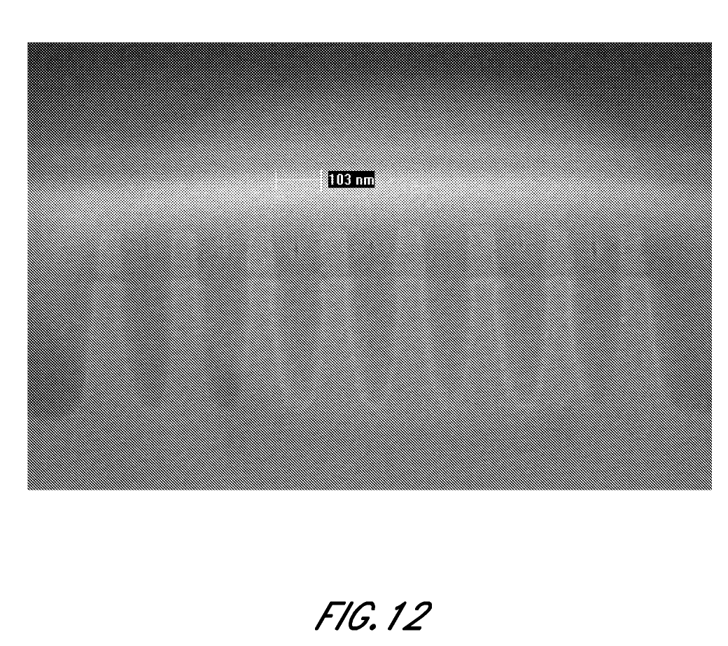

FIG. 11 illustrates the results of the deposition. Relative to Example 1 some voids are still apparent, although the voids created through using ozone are smaller than using oxygen gas.

### EXAMPLE 3

Silicon oxide was deposited into trenches using TEOS and O₃ as precursors. The trenches were about 100 nm wide, with an aspect ratio of about 4. The deposition was performed in a A412™ batch reactor from ASM International N.V. of Bilthoven, The Netherlands. TEOS was pulsed and ozone was flowed continuously, at a fixed rate, into the reaction chamber. TEOS was pulsed at about 450 sccm (714 pulses) and ozone was flowed at about 2.5 slm. The substrate temperature was about 600° C. and the reaction chamber pressure was about 750 mTorr. About 650 nm of silicon oxide was deposited.

The substrates were then annealed in two stages in an ASM A412™ wet oxide vertical furnace from ASM International N.V. of Bilthoven, The Netherlands. First, the substrates are annealed at 750° C. for 30 minutes in a steam atmosphere. Second, the substrates are annealed at 1050° C. for 30 minutes in a nitrogen atmosphere.

FIG. 13 illustrates the results of the deposition. Advantageously, the occurrence of voids was minimal and the voids that were formed were small.

It will be appreciated by those skilled in the art that various other omissions, additions and modifications may be made to the methods and structures described above without departing from the scope of the invention. All such modifications and changes are intended to fall within the scope of the invention, as defined by the appended claims.

What is claimed is:

1. A method for depositing silicon oxide, comprising:
providing a batch reactor;
providing a plurality of vertically separated substrates in a reaction chamber of the batch reactor;
chemical vapor depositing silicon oxide on the substrates, wherein chemical vapor depositing comprises:
pulsing tetraethyl orthosilicate (TEOS) into the reaction chamber; and
flowing ozone into the reaction chamber while maintaining a pressure inside the reaction chamber at about 10 Torr or less.

2. The method of claim 1, wherein the batch reactor accommodates 25 or more substrates.

3. The method of claim 1, wherein the batch reactor is a hot wall vertical furnace.

4. The method of claim 3, wherein walls of the reaction chamber are formed of quartz.

5. The method of claim 1, wherein the batch reactor comprises at least one injector having vertically spaced apart holes.

6. The method of claim 5, wherein pulsing TEOS comprises injecting TEOS into the reaction chamber out of the vertically spaced apart holes of the injector.

7. The method of claim 5, wherein flowing ozone comprises injecting ozone into the reaction chamber out of vertically spaced apart holes of the injector.

8. The method of claim 5, wherein the ozone is generated before being injected into the reaction chamber.

9. The method of claim 1, wherein pulsing TEOS comprises providing the TEOS to the reaction chamber by direct liquid injection.

10. The method of claim 9, wherein pulsing TEOS comprises providing substantially pure vapor phase TEOS into the reaction chamber.

11. A method for depositing silicon oxide on a substrate, comprising:
providing the substrate in a reaction chamber;
pulsing tetraethyl orthosilicate (TEOS) into the reaction chamber, wherein pulsing TEOS comprises varying the amount of TEOS flowed into the reaction chamber per pulse among a series of the pulses of TEOS;
flowing ozone into the reaction chamber; and
maintaining a pressure inside the reaction chamber at about 10 Torr or less.

12. The method of claim 11, wherein a deposition temperature of the substrate increases over a course of pulsing TEOS into the reaction chamber.

13. The method of claim 12, wherein a pressure of the reaction chamber decreases over a course of pulsing TEOS into the reaction chamber.

14. The method of claim 11, wherein flowing ozone is performed continuously during and between pulses of TEOS into the reaction chamber.

15. The method of claim 14, wherein a rate of flow of ozone into the reaction chamber is constant over the course of pulsing TEOS.

16. The method of claim 14, further comprising varying a rate of flow of ozone into the reaction chamber over the course of pulsing TEOS.

17. The method of claim 14, wherein the rate of flow of ozone into the reaction chamber decreases over the course of pulsing TEOS.

18. The method of claim 11, wherein flowing ozone comprises pulsing ozone into the reaction chamber.

19. The method of claim 18, wherein pulsing ozone and pulsing TEOS comprises providing alternating pulses of ozone and TEOS into the reaction chamber.

20. The method of claim 19, wherein an amount of ozone delivered to the reaction chamber per ozone pulse and an amount of TEOS delivered to the reaction chamber per TEOS pulse are substantially constant over the course of pulsing ozone and pulsing TEOS.

21. The method of claim 19, wherein an amount of TEOS delivered to the reaction chamber per TEOS pulse increases over the course of pulsing ozone and pulsing TEOS.

22. The method of claim 21, wherein an amount of ozone delivered to the reaction chamber per ozone pulse decreases over the course of pulsing ozone and pulsing TEOS.

23. The method of claim 19, further comprising purging the reaction chamber between pulses of TEOS and pulses of ozone.

24. The method of claim 11, wherein pulsing TEOS and flowing ozone comprises:
first, flowing TEOS and ozone into the reaction chamber at a first TEOS:ozone ratio;
second, flowing TEOS and the ozone into the reaction chamber at a second TEOS:ozone ratio higher than the first TEOS:ozone ratio; and
third, flowing TEOS and the ozone into the reaction chamber at a third TEOS:ozone ratio lower than the second TEOS:ozone ratio.

25. The method of claim 24, wherein flowing TEOS and ozone into the reaction chamber comprise alternatingly pulsing TEOS and ozone into the reaction chamber, wherein a TEOS pulse and an immediately following ozone pulse define a TEOS:ozone ratio.

26. A method for depositing silicon oxide, comprising:
providing a substrate in a reaction chamber, the substrate having a trench; and
filling the trench with silicon oxide, wherein filling the trench comprises:
pulsing tetraethyl orthosilicate (TEOS) into the reaction chamber;
flowing ozone into the reaction chamber; and
maintaining a pressure inside the reaction chamber at about 10 Torr or less.

27. The method of claim 26, wherein the trench has an aspect ratio of about four or greater.

28. The method of claim 26, further comprising annealing the substrate after filling the trench.

29. The method of claim 26, wherein filling the trench with silicon oxide comprises filling a bottom portion of the trench at a first temperature set point and a first pressure set point and filling an upper portion of the trench at a second temperature set point and a second pressure set point, wherein the second temperature set point is greater than the first temperature set point.

30. The method of claim 29, wherein the second pressure is greater than the first pressure.

31. The method of claim 26, wherein the pressure inside the reaction chamber is maintained between about 250 mTorr and 2000 mTorr.

32. The method of claim 31, wherein the temperature inside the reaction chamber is maintained between about 550° C. and 650° C.
